(19) United States
(12) Patent Application Publication
(10) Pub. No.: US 2017/0263789 A1
(43) Pub. Date: Sep. 14, 2017

(54) DESICCANT-BASED COOLING OF PHOTOVOLTAIC MODULES

(71) Applicant: Alliance for Sustainable Energy, LLC, Golden, CO (US)

(72) Inventor: Lin J. Simpson, Lakewood, CO (US)

(21) Appl. No.: 15/457,178

(22) Filed: Mar. 13, 2017

Related U.S. Application Data
(60) Provisional application No. 62/307,104, filed on Mar. 11, 2016.

(51) Int. Cl. H01L 31/024; H01L 31/0203; F25B 35/02; F25B 35/04; B01J 20/00; F25B 19/00

(52) U.S. Cl. CPC H01L 31/024; B01J 20/00; F25B 19/00; F25B 35/02; F25B 35/04; H01L 31/0203

(57) ABSTRACT

An example device includes a photovoltaic (PV) unit and a desiccant-based passive cooling component that is thermally coupled to the PV unit. The desiccant-based passive cooling component is configured to sorb, under first conditions, moisture from an environment that surrounds the device, via at least one of adsorption or absorption, and evaporate, under second conditions that are different from the first conditions, at least a portion of the moisture.

### CROSS-REFERENCE TO RELATED APPLICATIONS

This application claims the benefit of U.S. Provisional Application No. 62/307,104, filed Mar. 11, 2016, the entire content of which is incorporated herein by reference.

### CONTRACTUAL ORIGIN

The United States Government has rights in this invention under Contract No. DE-AC36-08GO28308 between the United States Department of Energy and Alliance for Sustainable Energy, LLC, the Manager and Operator of the National Renewable Energy Laboratory.

### BACKGROUND

Photovoltaic (PV) devices continue to become more ubiquitous. PV devices convert a portion of received sunlight into electrical power. However, a significant portion of the received sunlight is not converted to power, and instead becomes heat, causing the operating temperature of the PV devices to increase. Increased operating temperature can decrease device performance.

### SUMMARY

In one example, a device includes a photovoltaic (PV) unit and a desiccant-based passive cooling component that is thermally coupled to the PV unit. The desiccant-based passive cooling component is configured to sorb, under first conditions, moisture from an environment that surrounds the device, via at least one of adsorption or absorption, and evaporate, under second conditions that are different from the first conditions, at least a portion of the moisture.

In another example, a method includes sorbing, under first conditions, by a desiccant-based passive cooling component that is thermally coupled to a photovoltaic (PV) unit, moisture via at least one of adsorption or absorption, and obtaining, under second conditions that are different from the first conditions, by the desiccant-based passive cooling component and from the PV unit, heat energy sufficient to evaporate at least a portion of the moisture from the desiccant-based passive cooling component.

In another example, a method includes attaching, to a photovoltaic device, a desiccant-based passive cooling component such that the desiccant-based passive cooling component is thermally coupled to the photovoltaic device. The desiccant-based passive cooling component is configured to: sorb, under first conditions, moisture via at least one of adsorption or absorption and evaporate, under second conditions that are different from the first conditions, at least a portion of the moisture.

The details of one or more examples are set forth in the accompanying drawings and the description below. Other features, objects, and advantages will be apparent from the description and drawings, and from the claims.

### BRIEF DESCRIPTION OF DRAWINGS

FIGS. 1A and 1B are conceptual diagrams illustrating an example desiccant-cooled photovoltaic (PV) device, in accordance with one or more aspects of the present disclosure.

FIG. 2 is a conceptual diagram illustrating an example desiccant-cooled PV device, in accordance with one or more aspects of the present disclosure.

FIG. 3 is a conceptual diagram illustrating an example desiccant-cooled PV device, in accordance with one or more aspects of the present disclosure.

FIG. 4 is a graphical plot illustrating adsorption characteristics of silica gel and zeolite as a function of temperature and dew point.

FIG. 5 is a graphical plot illustrating temperature values of various PV devices over time, in accordance with one or more aspects of the present disclosure.

FIG. 6 is a graphical plot illustrating temperature values of various PV devices over time, in accordance with one or more aspects of the present disclosure.

FIG. 7 is a flow diagram illustrating example operations for desiccant-based cooling of photovoltaic modules, in accordance with one or more aspects of the present disclosure.

### DETAILED DESCRIPTION

The present disclosure provides systems, devices, and methods that use desiccants to reduce the temperature of PV devices and other electronic devices through moisture adsorption and evaporative cooling. For instance, a thin film of desiccant may be thermally coupled to a PV unit (e.g., a PV cell, a PV module, a PV panel, a PV array, etc.). When deployed for operation, the desiccant may adsorb water (e.g., from the ambient environment) during periods of relatively lower temperature (e.g., at night). As the temperature increases (e.g., during the day time), the water adsorbed (or absorbed) by the desiccant may evaporate. This endothermic process of evaporation may pull heat away from the PV device, thereby reducing the device temperature and improving device performance. That is, an evaporating liquid needs to take in heat energy in order to change from the liquid phase to a vapor. Water in a desiccant may obtain this heat energy from surrounding sources, such as a PV device to which the desiccant is thermally coupled.

It is estimated that approximately 80% of the solar energy collected by a PV device is converted to low-grade heat. Due to this fact, PV devices can heat up substantially during operation. For example, depending upon the specific environmental conditions (e.g., air temperature, humidity, irradiance, etc.), PV device temperatures can reach over 100 degrees Celsius.

Increased device temperatures increase the recombination rate of photo-generated carriers within the device. Additionally, as with other semiconductor devices, the band gap of PV materials decreases at higher temperatures. Both of these phenomena may contribute to a substantial decrease in conversion efficiency and thus power generated by the PV device. For example, device temperatures of 100 degrees Celsius can reduce power output by 40% or more. Such decreased conversion efficiency and/or power collection is due at least in part to a decrease in the open circuit voltage (V_{oc}) of the PV device.

In general, the average annual loss in PV power due to high device temperatures is approximately 10%. Thus, heating of PV devices has a significant effect on PV power generation. While a few types of PV devices have relatively lower losses, temperature-based efficiency degradation generally affects most types of PV devices. Reducing PV device temperatures by even 20 degrees Celsius on average may improve the absolute power output by up to 10%. This increased power output could mean billions of dollars per year in extra revenue for the 40-100 GW of PV devices newly installed each year. Furthermore, retrofit solutions could provide billions of dollars in extra revenue from gigawatts of extra power worldwide. This would be equivalent to about a 10% overall increase in power production, about a 10% overall reduction in PV plant costs, or approximately a 3% (or more) increase in absolute device efficiency (e.g., increasing the PV device efficiency from 21% to 24% or more).

While related art techniques have pursued other forms of passive temperature control for PV devices, the techniques described herein provide a number of distinct advantages. Firstly, desiccant-based cooling systems as described in the present disclosure may be implemented at relatively low-cost, potentially using $4 or less per m² of device area, or 2 cents or less per watt produced. Secondly, the techniques of the present disclosure may provide relatively lightweight passive cooling, compared to heat sinks or other related art technology. Furthermore, desiccant-based cooling systems as described herein may provide substantially improved cooling, as well. Desiccant-based cooling systems as described herein may be implemented in various setups, ranging from single-cell PV devices to entire solar power plants. In some examples, no connections to other resources (e.g., thermal loads, pumps, etc.) may be necessary, as opposed to other technologies such as combined heating/PV systems.

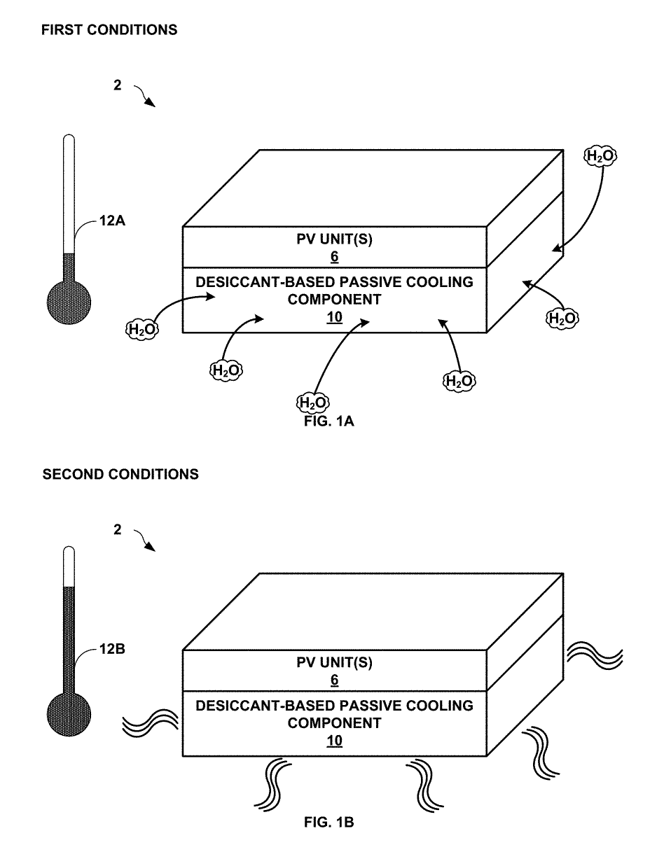

FIGS. 1A and 1B are conceptual diagrams illustrating an example desiccant-cooled PV device (e.g., PV device 2), in accordance with one or more aspects of the present disclosure. FIGS. 1A and 1B are not to scale. PV device 2 includes PV unit(s) 6 and desiccant-based passive cooling component 10. In various examples, one or more of the PV units may be thermally coupled to the desiccant-based passive cooling component. In some examples, PV device 2 may include additional or different components than those shown in the example of FIGS. 1A and 1B. The structure and configuration of PV device 2 as shown in the example of FIGS. 1A and 1B represents only one example of a desiccant-cooled PV device, and various other desiccant-cooled PV device configurations and structures are also within the scope of this disclosure.

PV units 6, as shown in the example of FIGS. 1A and 1B, represents any type of PV that may benefit from the desiccant-based cooling techniques described herein. For instance, PV units 6 may represent PV cells, PV modules, PV panels, PV arrays, or other collection of PV. PV units 6 may also be any type of PV, including silicon PV, cadmium telluride PV, copper-indium-gallium-selenide PV, perovskite PV, or any other PV types. In some examples, PV units 6 may be multi junction devices.

Desiccant-based passive cooling component 10, as shown in the example of FIGS. 1A and 1B, represents a component or portion of PV device 2 that includes a desiccant. The included desiccant may be any hygroscopic substance or any hydrophilic substance that, in a first temperature and humidity range, is capable of absorbing or adsorbing moisture from its ambient environment and, in a second temperature and humidity range, from which moisture may evaporate. In various examples, desiccant-based passive cooling component 10 may include a desiccant that is a solid, a liquid, or any combination thereof. Examples of a desiccant that may be included in desiccant-based passive cooling component 10 may include carbon (e.g., hygroscopic porous carbon), compound silica gel, calcium chloride, lithium chloride, lithium bromide, lithium acetate, potassium acetate, cesium fluoride, calcium chloride, magnesium chloride, magnesium acetate, sodium chloride, sodium formate, potassium formate, zinc bromide, sodium hydroxide, potassium hydroxide, sodium polyacrylate, compound sodium polyacrylate, lithium chloride intercalated sodium polyacrylate, some silica gels, and others. Additional examples include ionic liquids like 1,3-dimethylimidazolium acetate, 1,3-dimethylimidazolium chloride, 1-ethyl-3-methylimidazolium tetrafluoroborate, 1-ethyl-3-methylimidazolium acetate, and others. The type of desiccant used may be selected based on the operating conditions, as described below.

Desiccant-based passive cooling component 10 may be structured in various ways. As one example, desiccant-based passive cooling component 10 may be a thin desiccant film (e.g., having a thickness of about 10 mm or less) that is thermally coupled to PV units 6. As another example, such as when the desiccant included in desiccant-based passive cooling component 10 is a liquid or phase-changing material (e.g., lithium chloride, etc.), desiccant-based passive cooling component 10 may include a vapor-permeable container, such as a microporous membrane (polypropylene, polyethylene, polyethulenimine, polytetrafluoroethylene, polyvinylidene fluoride, etc.). Such a vapor-permeable container may allow water vapor or other vapor to pass through it while keeping liquids (e.g., water, salts, etc.) in (e.g., via surface tension). In some examples, the container may be hydrophobic. That is, the container may not absorb or adsorb water itself. In some examples, the container may be coated with a dense silicone or gel layer, in planar or hollow fiber structures, and/or having additional coatings like polytetrafluoroethylene. Important here is the ability of water vapor to pass between the desiccant and the environment while desiccant-based passive cooling component 10 holds the desiccant and liquid water close to PV units 6.

In some examples, desiccant-based passive cooling component 10 may be structured to improve moisture collection and/or evaporation. For instance, desiccant-based passive cooling component 10 and/or the desiccant included therein may have a honeycomb-like structure, or another structure for maximizing surface area. Other structures for desiccant-based passive cooling component 10 may include porous or highly porous solids. The desiccant included in desiccant-based passive cooling component 10 may, in some examples, be in sheet form or include ribbed structures to further increase contact area with the ambient air.

Desiccant-based passive cooling component 10 may be thermally coupled to PV units 6 (or one or more other components of PV device 2) in any way suitable to support heat transfer between desiccant-based passive cooling component 10 and the other components of PV device 2, in accordance with the techniques described herein. For instance, desiccant-based passive cooling component 10 could be affixed to PV units 6 using a glue that has good thermal conductivity. In some examples, desiccant-based passive cooling component 10 may include a container that could perform the duties of an encapsulant for PV units 6 as well as a desiccant.

In the example of FIGS. 1A and 1B, desiccant-based passive cooling component 10 is on the “bottom” (or “back”) of PV device 2. That is, desiccant-based passive cooling component 10 is attached to a side of PV units 6 that is opposite the side through which sunlight is received for electrical energy generation by PV units 10 (e.g., the “top” or “front”). In various examples, however, desiccant-based passive cooling component 10 may be in various other positions with respect to the other components of PV device 2. For instance, in some examples, such as examples in which desiccant-based passive cooling component 10 allows for the transmission of light, desiccant-based passive cooling component 10 may be on top of PV units 6. That is, in some examples sunlight may pass through desiccant-based passive cooling component 10 before being received by PV units 6 at a light-absorbing surface and converted to electrical energy.

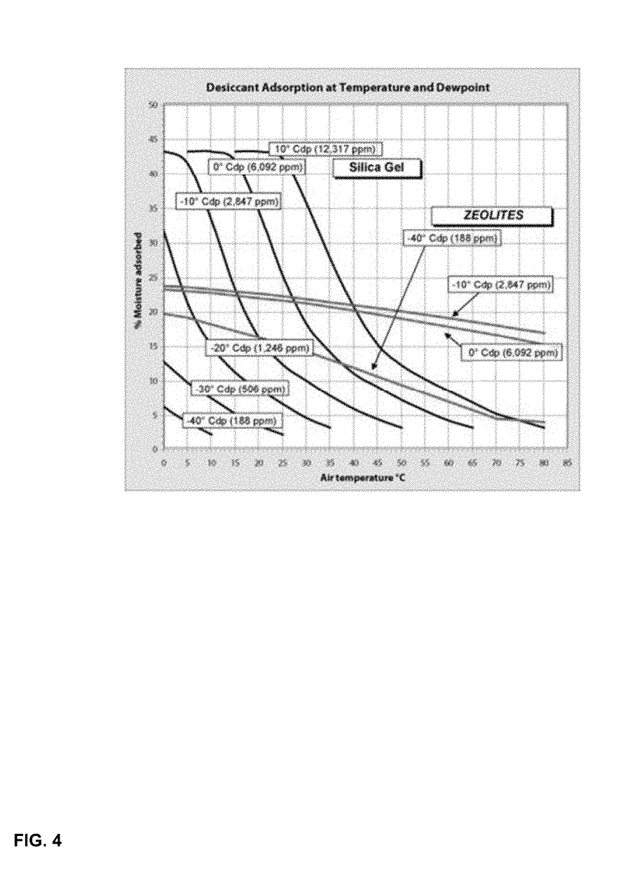

Conditions 12A, as shown in FIG. 1A, represent the first temperature and humidity range, while Conditions 12B, as shown in FIG. 1B, represent the second temperature and humidity range. The temperature ranges of conditions 12A and 12B may be ranges of the temperature of PV device 2, ranges of ambient air temperature around PV device 2, or a combination thereof. Specific temperature values and humidity values of conditions 12A and 12B may vary depending on the desiccant used in desiccant-based passive cooling component 10. That is, certain desiccants may be used as described herein when conditions 12A and 12B have a first set of ranges while other desiccants may provide improved functionality when conditions 12A and 12B have a different set of ranges. Example temperature and humidity ranges for example desiccants are further described with respect to FIG. 4, below.

In some examples, the ambient environment around PV device 2 may change based on time of day, weather conditions, or other factors. For example, conditions 12A may represent the conditions during night time, when the sun is not shining. Thus, conditions 12A may correspond to a relatively lower air temperature and/or device temperature. In contrast, conditions 12B may represent the conditions during the day time, when the sun is shining. Thus, conditions 12B may correspond to a relatively higher air temperature and/or device temperature. Other possible factors include cloud cover, general temperature changes (e.g., cold fronts and warm fronts), precipitation, or other changes, such as dust that impedes sunlight.

In some examples, conditions 12A may correspond to a higher humidity (e.g., a higher relative humidity) while conditions 12B may correspond to a lower humidity (e.g., a lower relative humidity). In some examples, the humidity may be approximately the same for both conditions 12A and 12B. In some examples, conditions 12B may correspond to a higher humidity than that of conditions 12A.

In general, in conditions 12A (e.g., night time), desiccant-based passive cooling component 10 may sorb (absorb or adsorb) moisture from the ambient environment. For instance, desiccant-based passive cooling component 10 may sorb water from the air, as shown in FIG. 1A. In some examples, desiccant-based passive cooling component 10 may sorb enough moisture to approximately saturate the desiccant material included in desiccant-based passive cooling component 10. That is, desiccant-based passive cooling component 10 may sorb the maximum amount of moisture that desiccant-based passive cooling component 10 is able to hold in conditions 12A. In other examples, desiccant-based passive cooling component 10 may sorb less moisture. Note, also, that in dry clear sky environments, PV devices may cool below the ambient air temperatures due to radiant heat transfer. In such conditions, the temperature of PV device 2 may be even lower than ambient air temperatures, which may aid in moisture absorption (or adsorption) during conditions 12A (e.g., due to water condensing on desiccant-based passive cooling component 10).

With reference to FIG. 1B, the ambient environment may change to conditions 12B. This change may be gradual or more pronounced. In conditions 12B (e.g., day time), moisture may start to evaporate from desiccant-based passive cooling component 10. That is, for instance, as the temperature of PV device 2 starts to increase (e.g., due to absorption of sunlight and/or an increased ambient temperature), the moisture holding capacity of the desiccant in desiccant-based passive cooling component 10 may be reduced, and the moisture held by desiccant-based passive cooling component 10 may exceed its changed moisture holding capacity. As a result, the moisture may begin to evaporate from desiccant-based passive cooling component 10. Evaporation is an endothermic process that uses heat to vaporize the moisture held in desiccant-based passive cooling component 10. The heat energy used to vaporize the moisture is carried away by the vaporized moisture, thereby reducing the heat energy existing in and around the un-evaporated moisture (and/or a material holding that moisture). Because desiccant-based passive cooling component 10 is thermally coupled to one or more other components of PV device 2, this evaporation may essentially “pull” heat from the one or more other components of PV device 2, thereby cooling PV device 2. This evaporative cooling may keep the temperature of PV PV device 2 closer to the wet bulb temperature (e.g., closer to the dew point of the ambient environment) and thus below the ambient air temperature. Alternatively, this evaporative cooling may reduce the temperature of PV device 2, but the temperature of PV device 2 may remain above the ambient air temperature.

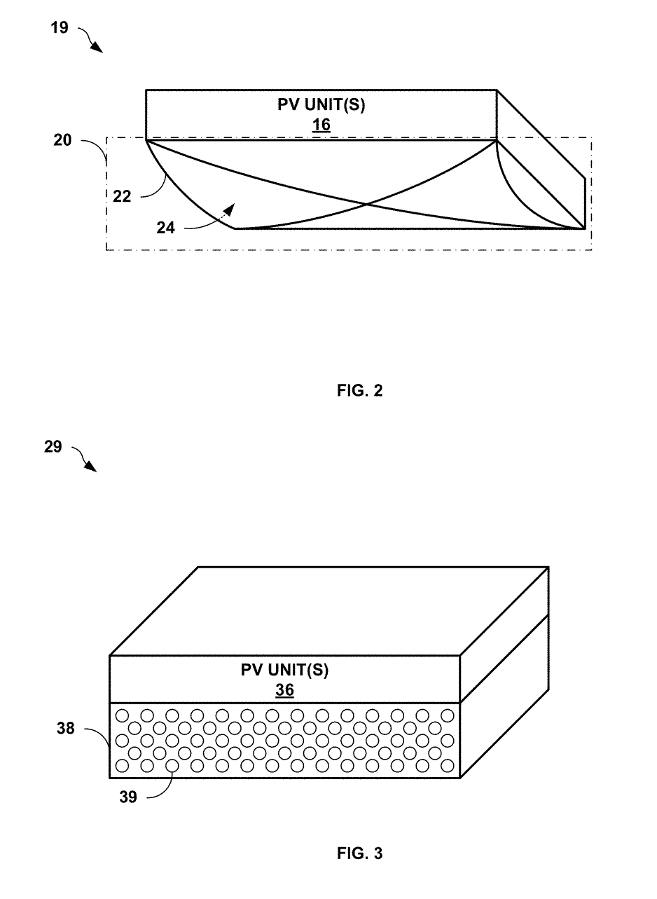

FIG. 2 is a conceptual diagram illustrating an example desiccant-cooled PV device (e.g., PV device 19), in accordance with one or more aspects of the present disclosure. FIG. 2 is not to scale. PV device 19 includes PV unit(s) 16 and desiccant-based passive cooling component 20. PV units 16 and desiccant-based passive cooling component 20 may have substantially the same functionality as PV units 6 and desiccant-based passive cooling component 10 described with respect to FIGS. 1A and 1B.

In the example of FIG. 2, desiccant-based passive cooling component 20 includes vapor-permeable container 22 and deliquescent desiccant 24. Deliquescent desiccant 24 may be a desiccant material that changes from a solid (e.g., powder) form to a liquid form when sufficient moisture is absorbed. Thus, in order to maintain thermal coupling between the desiccant and PV units 16, deliquescent desiccant 24 may be enclosed in a pouch or other container (e.g., vapor-permeable container 22) to hold the desiccant next to PV units 16 in both a liquid and solid form.

Vapor permeable container 22 may be configured to ensure that deliquescent desiccant 24 remains in place while allowing vapor (e.g., water vapor) to pass through the container. That is, vapor-permeable container 22 may allow air and other gases to pass through but may retain liquids and/or solids (e.g., based on surface tension of the liquids).

FIG. 3 is a conceptual diagram illustrating an example desiccant-cooled PV device, in accordance with one or more aspects of the present disclosure. FIG. 3 is not to scale. PV device 29 includes PV unit(s) 36 an desiccant-based passive cooling component 38. PV units 36 and desiccant-based passive cooling component 38 may have substantially the same functionality as PV units 6 and desiccant-based passive cooling component 10 described with respect to FIGS. 1A and 1B.

In the example of FIG. 3, desiccant-based passive cooling component 38 has a porous structure that has multiple recesses, including recess 39. Recess 39 (and others) may allow desiccant-based passive cooling component 38 to better sorb and desorb moisture, as there is more surface area for contacting the surrounding air. While shown in the example of FIG. 3 as being generally cylindrical holes, desiccant-based passive cooling component 38 may, in other examples, include any type and number of recesses. For example, desiccant-based passive cooling component 38 may, in some examples, have a honeycomb-like structure.

FIG. 4 is a graphical plot illustrating the adsorption characteristics of silica gel and zeolites as a function of temperature and dew point. As shown in FIG. 4, for a given dew point, silica gel adsorption can change significantly with even a 10 degree Celsius change in temperature. Thus, environmental conditions 12A and 12B, as shown in the example of FIGS. 1A and 1B, may not need to be significantly different in order for the desiccant-based cooling techniques described herein to improve device temperatures. Even with air temperature changes less than 20 degrees Celsius, by using the techniques described herein, a PV device may be kept as much as 20 degrees Celsius (or more) cooler than an equivalent PV device that does not use any cooling techniques. While zeolite or silica gel are shown in the example data of FIG. 4, various other desiccants may be even more suitable for common PV device operating environments. For instance, other desiccants may have increased amounts of water sorption/desorption for the relative humidity and temperatures commonly experienced by deployed PV devices. Furthermore, other desiccants described herein may have relatively higher water sorption capacities. Regardless, in various examples, the improved cooling that results from implementing the techniques described herein may be available all year long and may provide substantial cooling benefits even in cooler winter months.

The following table (Table I) provides example temperature and relative humidity values of first and second conditions under which a few desiccants may be used in accordance with the techniques described herein. Table I represents only one small set of example values and desiccants, and the desiccants referenced therein may be used under various other conditions in accordance with the present disclosure.

TABLE I

| | First | First | Second | Second |
|---|---|---|---|---|
| | Conditions | Conditions | Conditions | Conditions |
| | Temp | Relative | Temp | Relative |
| Desiccant | (° C.) | Humidity (%) | (° C.) | Humidity (%) |
| Potassium acetate | 20 | 90 | 60 | 20 |
| Compound lithium | 10 | 60 | 60 | 20 |
| chloride intercalated | | | | |
| sodium polyacrylate | | | | |

As shown in Table I, a material like potassium acetate may be able to sorb a substantial amount of water vapor under conditions that resemble the night time environment in many geographical areas. During conditions similar to the day time environment in the same areas, such loaded potassium acetate may provide up to 17° C. of cooling to PV modules. Furthermore, potassium acetate is non-corrosive, making it much more amenable to use with PV devices and other electronics.

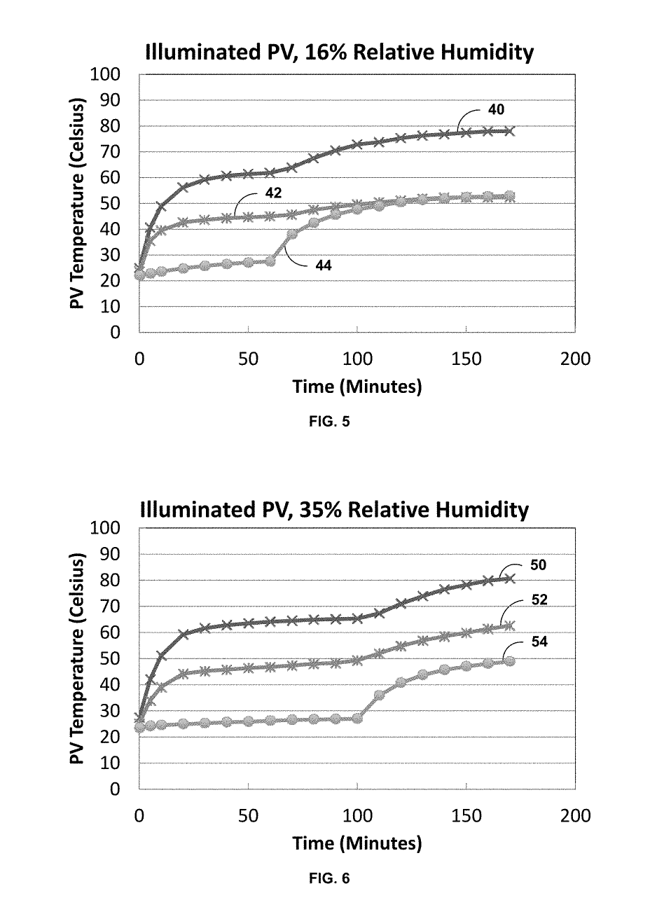

FIG. 5 is a graphical plot illustrating temperature values of various PV devices over time, in accordance with one or more aspects of the present disclosure. Specifically, FIG. 5 shows the temperature of PV devices both without desiccant cooling (e.g., line 40) and with desiccant cooling (e.g., line 42). The latter PV device used potassium chloride as the desiccant. The PV devices were initially subjected to 90% relative humidity and 25° C. temperatures for 16 hours without light illumination. Lines 40 and 42 indicate the temperature of the PV devices when illuminated with light, in a 16% relative humidity environment. The ambient air temperature is shown by line 44. The data shown in FIG. 5 clearly demonstrate that as the PV device temperatures increase with solar irradiance, the desiccant keeps the PV device cooler. At a high enough temperature, the PV device is actually cooler than the ambient air temperature. Ultimately, with an optimized desiccant, the cooling may be as good as theoretically using pure water. However, unlike water, the techniques described herein also allow for periodic “recharging” of the desiccant (e.g., during night time) in a passive fashion.

Due to the large heat capacity associated with the latent heat of vaporization/condensation of water in a desiccant, only a small amount of water retention may be needed to provide the cooling. As one example, for a solar irradiance of about 1000 W/m² and a PV panel converting about 20% of the solar irradiance to electricity, the heat load of the PV panel during the day may be less than about 600 W/m² for approximately 5 hours (i.e., 3 kWh/m²). Water evaporation from a desiccant may provide about 0.8 kWh/kg cooling, so that up to ˜4 kg/m² of water may be needed to cool the PV panel. Assuming approximately a 100 wt % water loading for a compound lithium chloride polyacrylate (e.g., approximately half of the maximum capacity) and no air cooling, a thin desiccant film of about 4 mm thick, when used as described herein, may provide sufficient cooling in these conditions.

With commercial desiccants available at about $0.20 per kg, this corresponds to a desiccant cost ranging from about $2/m² to about $4/m² per PV panel to provide desiccant-based cooling as described herein. Actual fielded desiccant cooling solutions may use much less material and thus may cost far less, especially when combined with other cooling technologies and/or using other desiccant materials (e.g., compound superabsorbent polymers, graphite, and others).

FIG. 6 is another graphical plot illustrating temperature values of various PV devices over time, in accordance with one or more aspects of the present disclosure. Specifically, FIG. 6 shows the temperature of PV devices both without desiccant cooling (e.g., line 50) and with desiccant cooling (e.g., line 52). The latter PV device used potassium acetate as a desiccant. The PV devices were initially subjected to 90% relative humidity and 25° C. temperatures for 16 hours without light illumination. Lines 50 and 52 indicate the temperature of the PV devices when illuminated with light, in a 35% relative humidity environment. The ambient air temperature is shown by line 54.

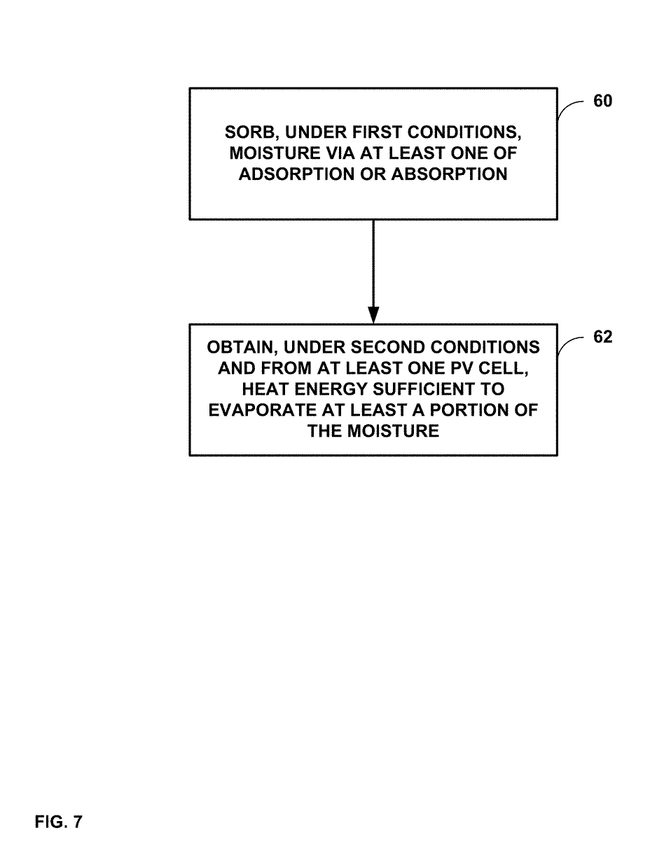

FIG. 7 is a flow diagram illustrating example operations for desiccant-based cooling of photovoltaic modules, in accordance with one or more aspects of the present disclosure. The operations of FIG. 7 are described below within the context of FIGS. 1A and 1B.

In the example of FIG. 7, a desiccant-based passive cooling component that is thermally coupled to a photovoltaic (PV) unit may sorb, under first conditions, moisture via at least one of adsorption or absorption (60). For instance, desiccant-based passive cooling component 10 of FIGS. 1A and 1B may adsorb, during conditions 12A, moisture from the air surround it and/or may absorb moisture that has condensed on its surface.

The desiccant-based passive cooling component may obtain, under second conditions that are different from the first conditions, heat energy, from the PV unit, sufficient to evaporate at least a portion of the moisture from the desiccant-based passive cooling component (62). For example, desiccant-based passive cooling component 10 may obtain heat from PV units 6 during conditions 12B, thereby causing the moisture sorbed by desiccant-based passive cooling component 10 to evaporate.

In some examples, the desiccant-based passive cooling component includes at least one of: lithium chloride, potassium acetate, lithium bromide, lithium acetate, cesium fluoride, calcium chloride, magnesium chloride, magnesium acetate, sodium chloride, sodium formate, potassium formate, zinc bromide, sodium hydroxide, potassium hydroxide, sodium polyacrylate, lithium chloride intercalated sodium polyacrylate, silica gel, 1,3-dimethylimidazolium acetate, 1,3-dimethylimidazolium chloride, 1-ethyl-3-methylimidazolium tetrafluoroborate, or 1-ethyl-3-methylimidazolium acetate.

An example device may include a photovoltaic (PV) unit and a desiccant-based passive cooling component that is thermally coupled to the PV unit. The desiccant-based passive cooling component may be configured to sorb, under first conditions, moisture from an environment that surrounds the device, via at least one of adsorption or absorption. The desiccant-based passive cooling component may also be configured to evaporate, under second conditions that are different from the first conditions, at least a portion of the moisture.

In some examples, the desiccant-based passive cooling component includes at least one of: lithium chloride, potassium acetate, lithium bromide, lithium acetate, cesium fluoride, calcium chloride, magnesium chloride, magnesium acetate, sodium chloride, sodium formate, potassium formate, zinc bromide, sodium hydroxide, potassium hydroxide, sodium polyacrylate, lithium chloride intercalated sodium polyacrylate, silica gel, 1,3-dimethylimidazolium acetate, 1,3-dimethylimidazolium chloride, 1-ethyl-3-methylimidazolium tetrafluoroborate, or 1-ethyl-3-methylimidazolium acetate. In some examples, the desiccant-based passive cooling component includes a deliquescent desiccant and a vapor-permeable container configured to retain the deliquescent desiccant, the deliquescent desiccant being disposed within the vapor-permeable container.

In some examples, the PV unit has a light-absorbing surface and a non-light absorbing surface, and the desiccant-based passive cooling component is a layer of material attached to the non-light absorbing surface. In some examples, the desiccant-based passive cooling component has a porous structure having at least one recess. In some examples, the moisture comprises water.

The techniques described herein may, in some examples, be applied to existing PV units. That is, the techniques of the present disclosure may be used to retrofit existing PV devices as well as provide new PV devices. As one example method, a desiccant-based passive cooling component may be attached to a photovoltaic device, such that the desiccant-based passive cooling component is thermally coupled to the photovoltaic device. The desiccant-based passive cooling component may be configured to: sorb, under first conditions, moisture via at least one of adsorption or absorption; and evaporate, under second conditions that are different from the first conditions, at least a portion of the moisture. In this way, existing PV devices may also benefit from the techniques described herein through a low-cost retrofit. In some examples, the desiccant-based passive cooling component includes at least one of: lithium chloride, potassium acetate, lithium bromide, lithium acetate, cesium fluoride, calcium chloride, magnesium chloride, magnesium acetate, sodium chloride, sodium formate, potassium formate, zinc bromide, sodium hydroxide, potassium hydroxide, sodium polyacrylate, lithium chloride intercalated sodium polyacrylate, silica gel, 1,3-dimethylimidazolium acetate, 1,3-dimethylimidazolium chloride, 1-ethyl-3-methylimidazolium tetrafluoroborate, or 1-ethyl-3-methylimidazolium acetate.

The impact of reducing the amount of unwanted heat-up of PV devices during solar energy generation may be very large, potentially resulting in up to about a 10% increase in power generation, for an equivalent overall plant capital cost reduction of up to about 10%. The impact to a PV plant system value may be billions of dollars per year, based on the anticipated global market of 200 GW per year. With retrofits, the desiccant cooling techniques described herein may result in billions of dollars in extra energy generation income. While the additional costs and other factors must be traded against the substantial increase in performance, the net benefit may be very large.

In accordance with the techniques described herein, thin films or other desiccant-based cooling components may be applied to existing or new PV devices (e.g., cells, modules, panels, and/or arrays) to provide purely passive cooling during the day when the solar energy that is not converted to electricity by the PV devices causes the devices to heat up. Effectively, the proposed desiccant-based cooling methods, systems, and processes may recharge at night with cooler temperatures and then keep the photovoltaic devices closer to the initial panel night-time temperature (i.e., less than the ambient air temperature during the day) during operation of the panel during the day to generate electricity.

The main defining factor affecting water sorption (absorption or adsorption) and desorption within a desiccant is the relative humidity. In accordance with the techniques described herein, a desiccant can be used to absorb (or adsorb) a sufficient amount of water from the ambient air around a PV device at night, when the relative humidity is higher. When the PV device temperature (and the ambient air temperature) increases during the day, the relative humidity of the air may typically decrease, and thus water from the desiccant may start to evaporate. This evaporation may cool the PV device by using heat energy “pulled” from the PV device that leaves with the evaporated water vapor.

Modeling has shown that this process, when considered using real temperature/humidity data and real desiccant characteristics, does cool PV devices as described. Furthermore, as shown in FIG. 5 and FIG. 6, experimental results show that PV modules typically heat to 50 degrees Celsius or more when the sun is shining, and thus there is a large amount of thermal energy to drive the water evaporation from a desiccant to provide cooling. These results also indicate that PV module temperature may be reduced by more than 10 degrees Celsius using the desiccant-based cooling techniques of the present disclosure, where water is uniquely passively replenished from the air, and then used to cool PV devices when the devices are generating electricity.

In some examples, desiccant and water vapor transport pathways may be optimized to obtain even greater operating temperature decreases in PV devices. Optimization may involve using materials/templates with good thermal conductivity and/or improving the porosity of the materials to provide improved water vapor transport to and from the desiccant. As one example, porous materials like compound super absorbent polymers may be used. As another example, desiccants may be integrated into honeycomb structures, such as those used in some “desiccant wheels.” However, unlike for typical cooling applications, where the desiccant increases in temperature and is mainly used to dry the air, the desiccant is used in the techniques described herein to directly cool illuminated PV devices and the like.

Optimization may also involve selecting the proper desiccant for the appropriate humidity and temperature ranges of interest for optimal PV cooling. For example, many clays and other natural materials are not hygroscopic enough to pull water from the air under the typical operating conditions of PV systems, and hold a relatively little amount of water relative to their own weight. However, materials like lithium chloride and potassium acetate generally sorb water at lower relative humidities, and can sorb more than 100% of their weight in water. Thus, using lithium chloride, potassium acetate, and/or similar materials may decrease the amount of desiccant needed. However, when these desiccants are fully loaded with water, they become a liquid. With such deliquescent materials, a vapor-permeable membrane may be used to contain these “liquid” desiccants.

In some examples, more “solid” desiccants such as compound sodium polyacrylate with intercalated lithium chloride or others may be used, as they can be formed or incorporated into more porous structures. Based on the temperature and humidity conditions of the PV site, desiccant material and/or desiccant properties may be adjusted to optimize PV power output as described herein.

The foregoing disclosure includes various examples set forth merely as illustration. The disclosed examples are not intended to be limiting. Modifications incorporating the spirit and substance of the described examples may occur to persons skilled in the art. These and other examples are within the scope of this disclosure and the following claims.

What is claimed is:

1. A device comprising:
a photovoltaic (PV) unit; and
a desiccant-based passive cooling component that is thermally coupled to the PV unit, wherein the desiccant-based passive cooling component is configured to:
sorb, under first conditions, moisture from an environment that surrounds the device, via at least one of adsorption or absorption, and
evaporate, under second conditions that are different from the first conditions, at least a portion of the moisture.

2. The device of claim 1, wherein the desiccant-based passive cooling component comprises at least one of: lithium chloride, potassium acetate, lithium bromide, lithium acetate, cesium fluoride, calcium chloride, magnesium chloride, magnesium acetate, sodium chloride, sodium formate, potassium formate, zinc bromide, sodium hydroxide, potassium hydroxide, sodium polyacrylate, lithium chloride intercalated sodium polyacrylate, silica gel, 1,3-dimethylimidazolium acetate, 1,3-dimethylimidazolium chloride, 1-ethyl-3-methylimidazolium tetrafluoroborate, or 1-ethyl-3-methylimidazolium acetate.

3. The device of claim 1, wherein the desiccant-based passive cooling component comprises:
a deliquescent desiccant; and
a vapor-permeable container configured to retain the deliquescent desiccant, the deliquescent desiccant being disposed within the vapor-permeable container.

4. The device of claim 1, wherein the PV unit has a light-absorbing surface and a non-light absorbing surface, and wherein the desiccant-based passive cooling component comprises a layer of material attached to the non-light absorbing surface.

5. The device of claim 1, wherein the desiccant-based passive cooling component comprises a porous structure having at least one recess.

6. The device of claim 1, wherein the moisture comprises water.

7. A method comprising:
sorbing, under first conditions, by a desiccant-based passive cooling component that is thermally coupled to a photovoltaic (PV) unit, moisture via at least one of adsorption or absorption; and
obtaining, under second conditions that are different from the first conditions, by the desiccant-based passive cooling component and from the PV unit, heat energy sufficient to evaporate at least a portion of the moisture from the desiccant-based passive cooling component.

8. The method of claim 7, wherein the desiccant-based passive cooling component comprises at least one of: lithium chloride, potassium acetate, lithium bromide, lithium acetate, cesium fluoride, calcium chloride, magnesium chloride, magnesium acetate, sodium chloride, sodium formate, potassium formate, zinc bromide, sodium hydroxide, potassium hydroxide, sodium polyacrylate, lithium chloride intercalated sodium polyacrylate, silica gel, 1,3-dimethylimidazolium acetate, 1,3-dimethylimidazolium chloride, 1-ethyl-3-methylimidazolium tetrafluoroborate, or 1-ethyl-3-methylimidazolium acetate.

9. A method comprising:
attaching, to a photovoltaic device, a desiccant-based passive cooling component such that the desiccant-based passive cooling component is thermally coupled to the photovoltaic device,
wherein the desiccant-based passive cooling component is configured to:
sorb, under first conditions, moisture via at least one of adsorption or absorption; and
evaporate, under second conditions that are different from the first conditions, at least a portion of the moisture.

10. The method of claim 9, wherein the desiccant-based passive cooling component comprises at least one of: lithium chloride, potassium acetate, lithium bromide, lithium acetate, cesium fluoride, calcium chloride, magnesium chloride, magnesium acetate, sodium chloride, sodium formate, potassium formate, zinc bromide, sodium hydroxide, potassium hydroxide, sodium polyacrylate, lithium chloride intercalated sodium polyacrylate, silica gel, 1,3-dimethylimidazolium acetate, 1,3-dimethylimidazolium chloride, 1-ethyl-3-methylimidazolium tetrafluoroborate, or 1-ethyl-3-methylimidazolium acetate.
